(19) United States
(12) Patent Application Publication
(10) Pub. No.: US 2006/0127597 A1
(43) Pub. Date: Jun. 15, 2006

(54) Method for producing containing fullerene and apparatus for producing same

(76) Inventors: Rikizo Hatakeyama, Miyagi (JP); Takamichi Hirata, Miyagi (JP); Kuniyoshi Yokoh, Miyagi (JP); Yasuhiko Kasama, Miyagi (JP); Kenji Omote, Miyagi (JP)

Correspondence Address: YOUNG & THOMPSON, 745 SOUTH 23RD STREET, 2ND FLOOR, ARLINGTON, VA, 22202, US

(21) Appl. No.: 10/528,561

(22) PCT Filed: Sep. 22, 2003
(86) PCT No.: PCT/JP03/12098

§ 371 Date: Oct. 3, 2005

(30) Foreign Application Priority Data
Sep. 20, 2002 (JP) 2002-276390

(51) Int. Cl. H05H 1/24; C23C 16/00; H01J 7/24

(52) U.S. Cl. 427/569; 427/248.1; 118/723 R; 315/111.21

(57) ABSTRACT

A method for producing endohedral fullerenes at a higher yield and an apparatus therefor are disclosed. The apparatus includes a vacuum vessel (1), elements (3, 4) for generating a plasma current (2) of atoms to be contained, elements (8) for introducing fullerenes into the plasma current (2), a holding member (6) for holding a plurality of division plates (5a, 5b, 5c) concentrically divided and arranged in the downstream region of the plasma current (2), and a bias-applying unit (7a, 7b, 7c) for applying an arbitrary bias voltage to the division plates (5a, 5b, 5c).

### TECHNICAL FIELD

The present invention relates to a method for producing endohedral fullerenes and a device therefor.

### BACKGROUND ART

A technical for producing of endohedral fullerenes, the technical as shown in FIG. 5 has been proposed (J. Plasma and Fusion Research, 75(8), 1999, August).

The technique consists of forming a plasma flow of an atom to be doped in an evacuated vessel, applying a jet stream of fullerenes thereto, and allowing fullerenes doped with the atom to deposit on a deposition plate placed downstream of the plasma flow to produce endohedral fullerenes.

According to this technique, it becomes possible to produce endohedral fullerenes at a high yield at a low temperature.

However, this technique is problematic in that the yield of endohedral fullerenes is rather low at the center of the plate. Specifically, when the yield of endohedral fullerenes is considered in terms of the radius of the plasma flow which has a circular cross-section, fullerenes successfully doped with the atom concentrate on the periphery whereas few fullerenes close to the center are doped with the atom.

Recently, the endohedral fullerene attracts attention because of its prospect use for a variety of applications, and the technique which enables the higher yield production of endohedral fullerenes than is possible with conventional techniques is demanded.

The present invention aims to provide a method enabling the higher yield production of endohedral fullerenes than is possible with conventional methods, and a device therefor.

### DISCLOSURE OF INVENTION

A method of the present invention for producing endohedral fullerenes comprises introducing, into an evacuated vessel, an atom to be doped towards a hot plate therein to form a plasma flow of the atom and introducing fullerenes into the plasma flow, thereby allowing resulting endohedral fullerenes to deposit on a deposition plate which has been set so as to be downstream of the plasma flow, wherein the deposition plate is composed of a plurality of concentric separate plate components, and the deposition of endohedral fullerenes is allowed to occur while a bias voltage is applied to the central plate component.

The method is characterized by applying a bias voltage Δ φ ap in the range of −5V<Δ φ ap<+20V to the central plate component.

The method is further characterized in that the radius R of the plate component at the center of the deposition plate is chosen to be R+5 mm or less when the radius of the hot plate is R.

The method is still further characterized in that means for measuring the density distribution of fullerene ions and doping atom ions in the plasma flow is provided ahead the deposition plate, and that the bias voltage is adjusted based on a signal from the means.

The method is still further characterized in that a cylinder whose inner cross-section has a radius of R+5 mm or more is provided in the course of the plasma flow, and that fullerenes are introduced from outside through an aperture formed on the wall of the cylinder.

Another method of the present invention for producing endohedral fullerenes comprises introducing, into an evacuated vessel, an atom to be doped towards a hot plate therein to form a plasma flow of the atom, and introducing fullerenes into the plasma flow, thereby allowing resulting endohedral fullerenes to be deposited on a deposition plate which has been set so as to be downstream of the plasma flow, wherein a cylinder whose inner radius is R+5 mm or more is provided in the course of the plasma flow, and fullerenes are introduced from outside through an aperture formed on the wall of the cylinder.

According to the method, the atom to be doped is an alkali metal atom.

According to the method, formation of a plasma flow of the doping atom is achieved by introducing the doping atom into the evacuated vessel towards the hot plate therein.

A device of the present invention for producing endohedral fullerenes comprises an evacuated vessel, means for forming a plasma flow of an atom to be doped, means for introducing fullerenes into the plasma flow, means for holding a deposition plate consisting of a plurality of concentric separate plate components which is set so as to be downstream of the plasma flow, and means for applying an appropriately chosen bias voltage to each of the separate plate components.

The bias voltage applying means is variable in its operation.

The bias voltage Δ φ ap applied to the central plate component is chosen to be in the range of −5V<Δ φ ap<+20V.

The radius of the central plate component is R+5 mm or less when the radius of the hot plate is R.

Means is provided for measuring the density distribution of fullerene ions and doping atom ions in the plasma flow ahead the deposition plate, and the bias voltage is adjusted based on a signal from the means.

A cylinder whose inner cross-section has a radius of R+5 mm or more is provided in the course of the plasma flow.

The device of the present invention for producing endohedral fullerenes whereby an atom to be doped is introduced into an evacuated vessel towards a hot plate therein to form a plasma flow of the atom, and fullerenes are introduced into the plasma flow so that resulting endohedral fullerenes are deposited on a deposition plate which has been set so as to be downstream of the plasma flow, comprises, in the course of the plasma flow, a cylinder in which the inner cross-section has a radius of R+5 mm or more.

The cylinder is placed with respect to the deposition plate such that, when the distance between the downstream end of the cylinder and the deposition plate is 1d, and length of the cylinder is 1c, 1d □ 2×1c.

The atom to be doped is an alkali metal atom.

The plasma flow forming means comprises a hot plate and a nozzle through which an atom to be doped is emitted towards the hot plate. Further provided is a cooling means for cooling at least the portion of the wall of the evacuated vessel surrounding the space downstream of the downstream end of the cylinder.

### BRIEF DESCRIPTION OF THE DRAWINGS

FIG. 1 is a diagram for showing the outline of a device for producing endohedral fullerenes representing an embodiment of the present invention.

FIG. 2 is a top view of a deposition plate comprising separate plate components shown in FIG. 1.

FIG. 3 shows a graph representing the density distribution of fullerene ions obtained in Example 1.

FIG. 4 shows a graph representing the density distribution or fullerene ions obtained in Example 3.

FIG. 5 is a diagram for showing the outline of a conventional technique used for the production of endohedral fullerenes.

### EXPRESSION OF REFERENCE LETTERS

1. Evacuated vessel

2. Plasma flow

3. Hot plate

4. Oven for heating an atom to be doped

5, 5a, 5b, 5c, Deposition plate comprising separate plate components

6. Introduction means (support means)

7a, 7b, 7c. Means for applying bias voltages

8. Sublimation oven for preparing fullerenes

10. Exhaust discharging pump

11. Electromagnet coil (coil for forming an external magnetic field)

13. Cylinder

14. Probe for measuring ions

15. Probe circuit

16. Computer

### BEST MODE FOR CARRYING OUT THE INVENTION

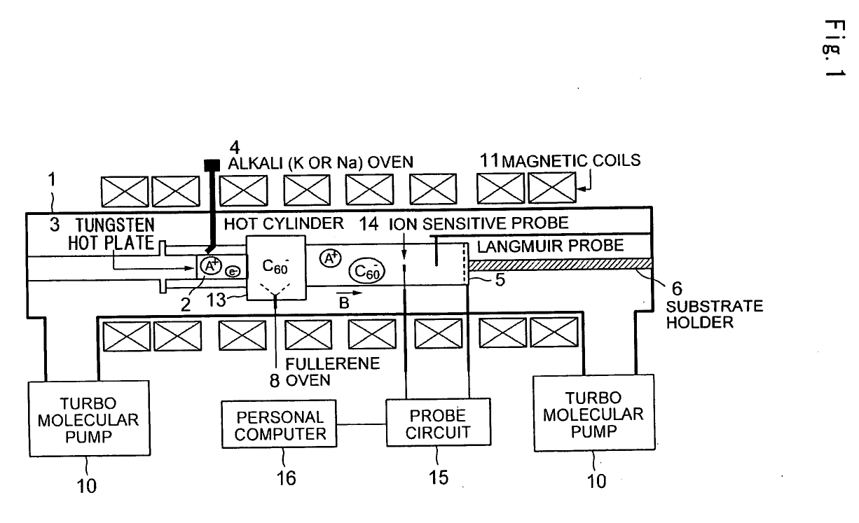

FIG. 1 shows the outline of a device for producing endohedral fullerenes representing an embodiment of the present invention.

The device comprises an evacuated vessel 1, means 3, 4 for forming a plasma flow 2 of an atom to be doped, means 8 for introducing fullerenes into the plasma flow 2, means 6 for holding a deposition plate composed of a plurality of concentrically arranged separate plate components 5a, 5b, 5c which is placed downstream of the plasma flow 2, and means 7a, 7b, 7c for applying an appropriately chosen bias voltage to each of the separate plate components 5a, 5b, 5c.

The operation of this device will be described in detail below.

In this embodiment, the means for forming a plasma flow of an atom to be doped comprises a hot plate 3 and an oven for vaporizing an alkali metal (an exemplary atom to be doped). When a jet of the vapor of an alkali metal which is to be doped is emitted from the oven 4 towards the tungsten hot plate 3 heated to about 2500° C., the metal gas become ionized as a result of the contact with the hot plate to form a plasma. The plasma thus generated is entrapped in the axial direction of the evacuated vessel 1 along a uniform magnetic field (B=2-7 kG) formed by an electromagnetic coil 11. The diameter of the hot plate 3 corresponds approximately to the diameter of the plasma flow. Thus, it is possible to produce a plasma flow having a desired diameter by varying the diameter of the hot plate as appropriate in correspondence with the size of the device.

Incidentally, around the external wall of the evacuated vessel 1 there is provided a cooling means (not illustrated). The internal wall of evacuated vessel 1 is cooled by virtue of the cooling means such that the internal wall of evacuated vessel 1 can capture neutral gas molecules. It is possible to produce a plasma free from contaminants by allowing neutral gas molecules to be adsorbed to the internal wall, and thus to allow highly pure endohedral fullerenes to be deposited on the deposition plate. In particular, if a cylinder 13 is introduced in the vessel 1, the cooling means is preferably set with respect to the evacuated vessel 1 such that at least a portion of the inner wall of evacuated vessel 1 surrounding the space between the downstream end of the cylinder 13 and the deposition plate 5 can be cooled. The temperature of the inner wall of evacuated vessel 1 is preferably kept at room temperature or lower, more preferably 0° C. or lower. If the temperature in question is kept within the above range, the adsorption of neutral gas molecules to the inner wall will be facilitated, and acquisition of highly pure endohedral fullerenes will be accomplished.

In this embodiment, a copper-made cylinder 13 is introduced with respect to the evacuated vessel 1 so that the cylinder 13 can surround the plasma flow 2 in its course. The cylinder 13 has an aperture on its wall so that fullerenes injected trough the aperture can be introduced into the plasma flow 2. During this operation, the cylinder 13 is heated to 400-650° C. After being introduced into the interior of cylinder 13, a portion of fullerenes that are not ionized in contact with the plasma are adsorbed to the inner wall of cylinder 13 to be sublimated again. If the temperature of cylinder 13 is below 400° C., renewed sublimation of adsorbed fullerenes would not occur effectively. On the contrary, if the temperature of cylinder 13 is over 650° C., renewed sublimation would produce superfluous C₆₀ which would result in the overproduction of C₆₀ not doped with Na, thus impairing the efficient utilization of C₆₀. Accordingly, the temperature of cylinder 13 is preferably kept at 400-650° C.

The radius of the inner wall of cylinder 13 is preferably set to R+5 mm or more, when the radius of the hot plate is R.

If the inner radius of cylinder 13 were below R+5 mm, the interaction between the plasma flow and cylinder 13 would become so large that retention of the plasma by cylinder 13 would be impaired which would then lead to the reduced yield of endohedral fullerenes.

On the contrary, if the inner radius of cylinder 13 were too large, this would cause problems such as the enlargement of the device, and impaired entrapment of plasma by the cylinder 13. Accordingly, the inner radius of cylinder 13 is preferably chosen to be R+5 cm or less. As long as the inner radius of cylinder 13 is R+5 cm or less, secure entrapment of plasma by cylinder 13 is ensured. More preferably the inner radius of cylinder 13 is chosen to be R+2 cm or less. Then, it will be possible to increase the density of plasma to a sufficiently high level to increase the chance of ions to react with each other which is necessary for the formation of endohedral fullerenes.

With devices like the one shown in FIG. 5, the yield of endohedral fullerenes varies from one device to another. The present inventors discovered that the inner radius of the cylinder is deeply involved in the determination of the yield of endohedral fullerenes, specifically in the determination of the radius of plasma flow. They further discovered that restricting the inner radius of the cylinder to a limited range of (R+5 mm) to (R+2 cm) can ensure the markedly high yield of endohedral fullerenes.

When a jet of fullerenes is introduced through an aperture into the cylinder 3, upon entry the jet expands with a certain expansion angle θ. The expansion angle θ of the jet upon entry is preferably kept in the range of 90-120°. Provided that the expansion angle θ is kept within the above range, introduction of fullerenes into plasma occurs highly efficiently, and the yield of endohedral fullerenes is increased. Incidentally, to alter the expansion angle θ, it is only necessary to vary the ratio between the diameter and the length of an inlet nozzle through which fullerenes are introduced into the cylinder.

In the embodiment shown in FIG. 1, fullerenes are depicted to introduce the cylinder from down upward in the figure. However, fullerenes may be introduced from up downward. Alternatively, fullerenes may be introduced from both sides simultaneously.

The speed at which fullerens are introduced may be adjusted by changing the temperature increment of the oven for fullerene sublimation. The temperature increment of the oven is preferably chosen to be 100° C./min or higher. The upper limit of the temperature increment is the maximum temperature increment at which bumping is safely avoidable,

The distance 1u between the upstream end of cylinder 13 (in the upper left corner of the figure) and the hot plate is preferably chosen to be (1.5 to 2.0)×(nDH²/4) where DH represents the outer diameter of the hot plate. If the distance 1u is chosen as described above, it will be possible to prevent the cylinder 13 from being exposed to heat from the hot plate, which will lead to the stable production of plasma over time.

In the evacuated vessel 1, there is provided, ahead of the deposition plate 5, an ion measurement probe 14 for measuring the density distribution of ions. The signal from the probe 14 is transmitted to a probe circuit 15 and a personal computer 16 so that the bias voltage to be applied to the deposition plate 5 can be adjusted based on the signal.

Control of the bias voltage based on the measured density distribution of ions is performed, for example, through the following procedure. To the ion measurement probe 14, a bias voltage is applied which corresponds to the potential of the plasma, and resulting current passing through the probe is measured. The ion density of plasma is determined by calculation from the measurement of current passing through the probe. If a positive bias voltage is applied to the probe, fullerene ions which are negatively charged flow into the probe, and the density of the ions can be determined by way of the measurement of the current. On the contrary, if a negative bias voltage is applied to the probe, it is possible to determine the density of positive ions such as Na ions to be doped. By changing the polarity of bias voltage applied to the probe and by moving the probe radially in terms of the cross-section of plasma, one can determine the density distributions of the ions of doping atom as well as those of fullerenes by measuring the probe current. On the basis of the measurement of the density distribution of the ions, the bias voltage applied to each of the separate plate components of the deposition plate upon which endohedral fullerenes will deposit is adjusted according to the following criteria.

At a measurement site corresponding to each of the separate plate components,

(1) ion density of fullerenes>ion density of doping ions,

→ bias voltage to the plate component is decreased.

(2) ion density of fullerenes<ion density of doping ions,

→ bias voltage to the plate component is increased.

(3) ion density of fullerenes □ density of doping ions,

→ bias voltage to the plate component remains unchanged.

The bias voltage should be adjusted as appropriate according to the difference between the density of fullerens and that of the doping atom.

At the leading end of plasma flow 2 there is the deposition plate 5 held by an introducing means 6 (holding means).

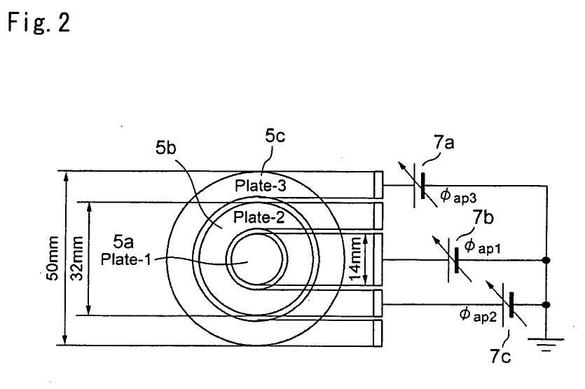

The deposition plate 5 is divided into separate concentric plate components as shown in FIG. 2. In the particular embodiment shown in FIG. 2, the deposition plate is divided into three separate plate components 5a, 5b, 5c. Specifically, the central plate component 5a is circular in form; and around the central plate component 5a, there are annular plate components 5b, 5c, which are electrically insulated from the central plate component 5a. The number of the plate components is not limited to three, but may be two or four or more. To the plate components 5a, 5b, 5c, there are attached respective bias applying means 7a, 7b, 7c so that bias voltages can be applied to the plate components independently of each other. The shape of the deposition plate is not limited to a circle or an annulus, but may be a solid rectangle or an open rectangle or any other shape, as long as that shape is compatible with the shape of the evacuated vessel.

The radius of the central plate component 5a is preferably R+5 mm or less when the radius of the hot plate is R. Even if the radius in question is made larger than R+5 mm, endohedral fullerenes are unlikely to deposit on the periphery outside the circle having a radius of R+5 mm. The device is preferably made as small as possible to maintain a high level of vacuum and reduce the pumping time required for the development of necessary vacuum. For the efficient utilization of developed fullerenes and for the compaction of the device, it is preferable to allow the central plate component to have a radius of R+5 mm or less. Even if the deposition plate is used intact without being divided into a plurality of components as above and the same bias voltage is applied to the entire deposition plate, it is possible to obtain endohedral fullerenes by choosing optimized deposition conditions.

The radius of a plasma flow entrapped in a magnetic field with a magnetic intensity of B is larger than the radius of the hot plate responsible for the development of the plasma flow by the Larmor radius R_{L} of the ions forming the plasma. R_{L} is inversely proportional to B, and if B=0.3T for example, it is possible when the temperature of the plasma is 2500° C. to estimate:

R_{L}=1.1 mm for Na ions, R_{L}=4.0 mm for C₆₀. It is preferable to design the dimension of a deposition plate taking R+5 mm as the standard of its radius, and considering the production conditions including the employable ranges in the intensity of magnetic field and temperature of plasma.

A bias voltage is applied to the central plate component 5a. Preferably a positive bias voltage is applied. This will emphasize the interaction between doping ions and fullerene ions, which will increase the likeliness of doping ions to be entrapped in fullerenes. However, even if the central plate component Sa does not receive the application of a bias voltage and is isolated in potential from the ground, it is still possible to obtain endohedral fullerens by optimizing the deposition conditions.

When a bias voltage is applied to the central plate component 5a, it is preferable to adjust the bias voltage such that the density of fullerenes has a peak at the center of plasma flow 2, then it will be possible to increase the fraction of endohedral fullerenes. The optimum bias voltage to achieve the above may vary depending on the species of doping ions, type of fullerens and condition of fullerene deposition. The optimum bias voltage under a given production condition can be readily determined in advance by a pilot experiment.

Assume, for example, that the doping atom is an alkali metal, and the fullerene is C₆₀. Then, a bias voltage φ ap in the range of −5V<φ ap<+20V is preferably applied to the central plate component 5. A bias voltage in the range of 0V □ φ ap □ +18V is particularly preferred.

The plate components 5b, 5c distinct from the central plate component 5a may be isolated in potential from the ground. Even if the plate component 5b is isolated from the ground, the same amount of endohedral fullerenes will deposit on that plate as are observed on a conventional plate. With respect to the overall yield of endoheral fullerenes for the entire deposition plate, however, the yield is still higher as compared with a conventional device, because the yield at the central plate component 5a remains higher than the corresponding yield of the conventional device.

Of course, it is possible to apply a bias voltage to the plate component 5b as appropriate when the density of fullerene ions in contact with the plate component 5b becomes low as a result of the fluctuation of fullerene deposition, so as to increase the density of the fullerene ions. Throughout the deposition of endohedral fullerenes, the density of ions may be monitored with the ion measurement probe 11, and controlled bias voltages may be automatically supplied to the plate components 5b, 5c by way of a computer 16. A controlled bias voltage may be automatically supplied to the central plate component 5a in the same manner.

To the evacuated vessel 1 is attached a pump 10 for evacuating gas from the vessel 1 to produce vacuum there.

Suitable fullerenes to be used according to the present invention may include, for example, Cn (n=60, 70, 74, 82, 84, . . . ).

It is possible to further reduce the concentration of neutral fullerenes contained in a membrane deposited on the deposition plate by adjusting the distance 1d between the downstream end of the cylinder and the deposition plate such that 1d □ 2×1c where 1c represents the length of the cylinder. Namely, it is possible by so doing to further increase the concentration of endohedral fullerenes contained in the membrane.

### EXAMPLES

### Example 1

Production of sodium doped C₆₀ (Na@C₆₀) fullerenes was performed using a device as shown in FIG. 1.

In this example, a cylindrical vessel 1 of 100 mm in diameter and 1200 mm in length was used to serve as a vacuum chamber.

The hot plate used in this example was a tungsten hot plate having a diameter of φ 20 mm, that is, its radius R is 10 mm. The tungsten hot plate 3 was heated to 2500° C. Sodium was emitted from an oven 4 towards the heated hot plate 3. The pressure within the evacuated vessel 1 was maintained at 1×10⁻⁴ Pa, and the intensity B of a magnetic field was kept at B=0.3T.

In the course of a plasma flow 2, there was provided a copper cylinder 13 with an aperture. The copper cylinder 13 used in this example was a cylinder having an inner diameter of 30 mm. The cylinder 13 was heated to about 400° C.

Then, fullerenes were introduced through the aperture of cylinder 13.

The deposition plate used in the example was a plate consisting of three plate components. The central plate component 5a had a diameter of 14 mm. A plate component 5b external to the central plate component had a diameter of 32 mm. The most external plate component had a diameter of 50 mm.

To the central plate component 5a, a bias voltage Δ φ ap (=φ ap−φ s) which was Δ φ ap=5V was applied. The plate components 5b, 5c were isolated from the ground. Here, φ ap represents a DC voltage while φ s represents the potential of plasma in suspension.

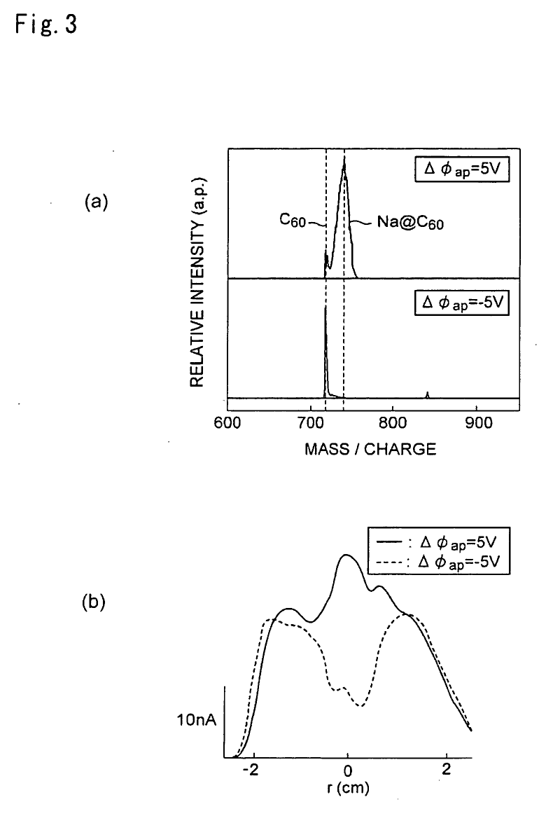

When an ion measurement probe 14 was used to measure the distribution of ions during the deposition of fullerenes, the distribution of ions along the radius r of plasma as represented by the solid line in FIG. 3(b) was obtained. Thus, the result suggests that Na⁺ ions concentrate at the central region of plasma.

After fullerenes were allowed to deposit for 30 minutes, the profile of fractional endohedral fullerenes (Na@C₆₀ in this example) deposited on the deposition plate was followed. It was found that the membrane component deposited on the central plate component 5a contained a high fraction of endohedral fullerenes. Furthermore, it was found that the membrane component deposited on the plate component 5b peripheral to the central plate component also contained a definite amount of endohedral fullerenes.

The result of mass spectrometry is presented in FIG. 3(a).

### Example 2

In this example, it was studied what effect varying the diameter of the cylinder 13 has on the yield.

The inner radius D of cylinder 13 was made 15, 20, 25, 35, 40 and 50 mm, fullerenes were allowed to deposit in the same manner as in Example 1, and the yield of endohedral fullerenes was followed.

When the yield of endohedral fullerenes obtained at the central plate component in Example 1 (where Dc=30 mm) is made 1 as a reference, following results were obtained,

15 mm (R+5 mm): 0.9

20 mm (R+10 mm): 0.9

25 mm (R+15 mm): 0.95

30 mm (R+20 mm): 1

35 mm (R+25 mm): 0.8

40 mm (R+30 mm): 0.7

50 mm (R+40 mm): 0.5

It is indicated that the yield is far higher when the inner radius of cylinder 13 relative to the radius R of the hot plate is allowed to take a value between R+15 mm and R+20 mm than the case where it takes a value outside the above range.

### Example 3

In this example, the bias voltage applied to the central plate component was varied in the range of −10V to 20V, and the deposition of endoheral fullerenes was followed.

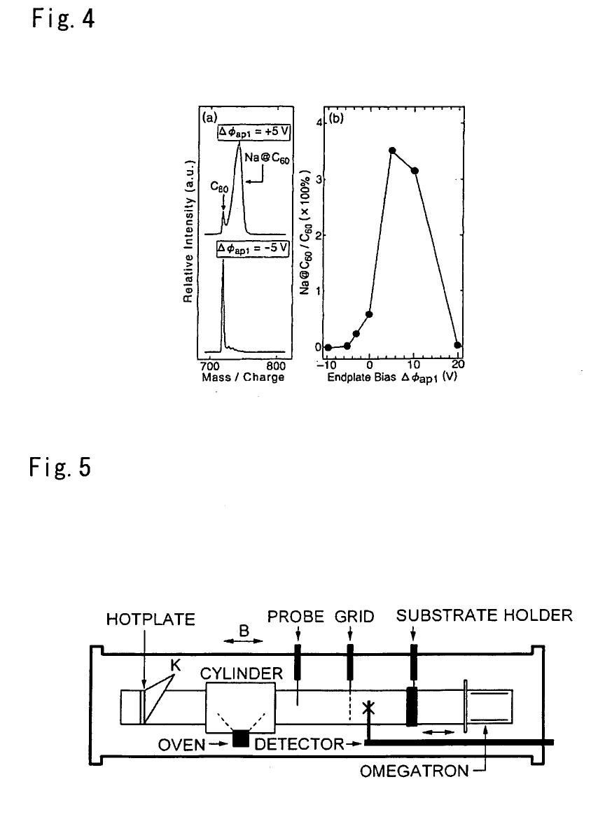

The results are shown in FIG. 4

Excellent yields of endohedral fullerenes were found to be obtained in the range of −5V<φ ap<+20V. It is indicated that still higher yields were obtained at 0V □ φ ap □ +18V.

### INDUSTRIAL APPLICABILITY

According to the present invention, it is possible to obtain endohedral fullerens even at the central portion of a deposition plate serving as a substrate, which leads to the improvement of the overall yield of endohedral fullerenes.

1. A method for producing endohedral fullerenes comprising: introducing, into an evacuated vessel, an atom to be doped towards a hot plate therein to form a plasma flow of the atom; and
introducing fullerenes into the plasma flow, thereby allowing resulting endohedral fullerenes to be deposited on a deposition plate which has been set so as to be downstream of the plasma flow,
wherein the deposition plate is composed of a plurality of concentric separate plate components, and the deposition of fullerenes is allowed to occur while a bias voltage is applied to the central plate component.

2. A method as described in claim 1 wherein a bias voltage Δφap in the range of −5V<Δφap<+20V is applied to the central plate component.

3. A method as described in claim 1 wherein the radius R of the plate component at the center of the deposition plate is chosen to be R+5 mm or less when the radius of the hot plate is R.

4. A method as described in claim 1 wherein means for measuring the density distribution of fullerene ions and doping atom ions in the plasma flow is provided ahead the deposition plate, and the bias voltage is adjusted based on a signal from said means.

5. A method as described in claim 1 wherein a cylinder whose inner cross-section has a radius of R+5 mm or more is provided in the course of the plasma flow when the radius of the hot plate is R, and fullerenes are introduced from outside through an aperture formed on the wall of the cylinder.

6. A method for producing endohedral fullerenes comprising:
introducing, into an evacuated vessel, an atom to be doped towards a hot plate therein to form a plasma flow of the atom; and
introducing fullerenes into the plasma flow, thereby allowing resulting endohedral fullerenes to be deposited on a deposition plate which has been set so as to be downstream of the plasma flow,
wherein a cylinder whose inner radius is R+5 mm or more is provided in the course of the plasma flow when the radius of the hot plate is R, and fullerenes are introduced from outside through an aperture formed on the wall of the cylinder.

7. A method as described in claim 1 wherein the atom to be doped is an alkali metal atom.

8. A device for producing endohedral fullerenes comprising:
an evacuated vessel;
means for forming a plasma flow of an atom to be doped;
means for introducing fullerenes into the plasma flow;
means for holding a deposition plate consisting of a plurality of concentric separate plate components which is set so as to be downstream of the plasma flow; and
means for applying bias voltages appropriately chosen independently of each other to the respective separate plate components.

9. A device as described in claim 8 wherein formation of a plasma flow of the doping atom is achieved by introducing the doping atom towards the hot plate therein.

10. A device as described in claim 8 wherein the bias voltage applying means is variable in its operation.

11. A device as described in claim 8 wherein the bias voltage Δφap applied to the central plate component is chosen to be in the range of −5V<Δφap<20V.

12. A device as described in claim 8 wherein the radius of the central plate component is R+5 mm or less when the radius of the hot plate is R.

13. A device as described in claim 8 wherein means for measuring the density distribution of fullerene ions and doping atom ions in the plasma flow is provided ahead the deposition plate, and the bias voltage is adjusted based on a signal from the means.

14. A device as described in claim 8 wherein a cylinder whose inner cross-section has a radius of R+5 mm or more is provided in the course of the plasma flow when the radius of the hot plate is R.

15. A device for producing endohedral fullerenes whereby an atom to be doped is introduced into an evacuated vessel towards a hot plate therein to form a plasma flow of the atom, and fullerenes are introduced into the plasma flow so that resulting endohedral fullerenes are deposited on a deposition plate which has been set so as to be downstream of the plasma flow, comprises, in the course of the plasma flow, a cylinder in which the inner crosssection has a radius of R+5 mm or more when the radius of a hot plate is R.

16. A device as described in claim 14 wherein the cylinder is placed with respect to the deposition plate such that, when the distance between the downstream end of the cylinder and the deposition plate is 1d, and length of the cylinder is 1c, 1d_{—}2×1c.

17. A device as described in claim 8 wherein the atom to be doped is an alkali metal atom.

18. A device as described in claim 8 wherein the plasma flow forming means comprises a hot plate and a nozzle through which an atom to be doped is introduced towards the hot plate.

19. A device as described in claim 8 further comprising a cooling means for cooling at least the portion of the wall of the evacuated vessel surrounding the space downstream of the downstream end of the cylinder.
